(19) United States
(12) Patent Application Publication
(10) Pub. No.: US 2025/0287826 A1
(43) Pub. Date: Sep. 11, 2025

(54) BONDING APPARATUS FOR DISPLAY APPARATUS

(71) Applicant: Samsung Display Co., LTD., Yongin-si (KR)

(72) Inventor: Jungseon PARK, Yongin-si (KR)

(21) Appl. No.: 19/072,061

(22) Filed: Mar. 6, 2025

(30) Foreign Application Priority Data
Mar. 8, 2024 (KR) 10-2024-0033320

(51) Int. Cl. H10K 71/50; H10K 59/12; H10K 59/127

(52) U.S. Cl. CPC H10K 71/50; H10K 59/1201; H10K 59/1275

(57) ABSTRACT

A bonding apparatus for a display apparatus includes a first support unit on which a first panel is mounted and a second support unit on which a second panel is bonded to the first panel is mounted, wherein the second support unit includes a stage on which the second panel is mounted, a main support portion arranged below the stage and supporting the stage, wherein the stage is rotated with the main support portion as a rotation axis as the main support portion is rotated, a sub-support portion connected below the stage and supporting the stage, wherein the sub-support portion slidingly moves on a plane which is perpendicular to the rotation axis as the stage is rotated, and a base plate supporting the main support portion and the sub-support portion.

This application claims priority to Korean Patent Application No. 10-2024-0033320, filed on Mar. 8, 2024, and all the benefits accruing therefrom under 35 USC § 119, the content of which in its entirety is herein incorporated by reference.

### BACKGROUND

### 1. Field

The invention relates to a bonding apparatus for a display apparatus, and more particularly, to a bonding apparatus for a display apparatus which is capable of bonding panels with increased precision.

### 2. Description of the Related Art

Recently, various electronic devices, such as mobile electronic devices and stationary electronic devices, have been used. Such electronic devices include display apparatuses for providing visual information such as an image or a video to a user for supporting various functions.

Generally, a display apparatus may include a display panel and a display circuit board, where the display panel displays an image and the display circuit board is electrically connected to the display panel and for transmitting signals thereto. The display panel and the display circuit board may be bonded and connected to each other by a bonding apparatus for the display apparatus.

### SUMMARY

To bond a display panel to a display circuit board, the display panel and the display circuit board may be aligned with each other and pressed against each other by a pressing unit. However, in the related art, a support portion that withstands the pressing force of the pressing unit typically has one shaft, and thus, problems such as deflection or pushing of a stage due to eccentricity may occur.

One or more embodiments include a bonding apparatus for a display apparatus, which is capable of bonding a display panel to a display circuit board with increased precision.

According to an embodiment, a bonding apparatus for a display apparatus, includes a first support unit on which a first panel is mounted and a second support unit on which a second panel which is bonded to the first panel is mounted, wherein the second support unit includes a stage on which the second panel is mounted, a main support portion arranged below the stage and supporting the stage, wherein the stage is rotated with the main support portion as a rotation axis as the main support portion is rotated, a sub-support portion connected below the stage and supporting the stage, wherein the sub-support portion slidingly moves on a plane which is perpendicular to the rotation axis as the stage is rotated, and a base plate supporting the main support portion and the sub-support portion.

In an embodiment, the main support portion and the sub-support portion may be arranged to be spaced apart from each other by a first distance, and while the stage is being rotated, the first distance between the main support portion and the sub-support portion may be maintained to be constant.

In an embodiment and in a plan view, as the state is rotated, the sub-support portion may linearly move in a first direction and a second direction crossing the first direction on the plane which is perpendicular to the rotation axis.

In an embodiment, the sub-support portion may include a first linear movement portion arranged on the base plate and linearly moving in the first direction, a connection plate connected above the first linear movement portion, and a second linear movement portion arranged on the connection plate and linearly moving in the second direction.

In an embodiment and in a plan view, the sub-support portion may perform a curve motion with respect to the main support portion as the main support portion is rotated.

In an embodiment, the sub-support portion may include a curvature movement portion arranged on the base plate and having a curved shape and a connection plate connected above the curvature movement portion.

In an embodiment, the sub-support portion may be provided in plural and may be arranged at each of both sides of the main support portion in a plan view.

In an embodiment, the sub-support portion may be provided in plural and may be arranged at each of an upper side, a lower side, a right side, and a left side of the main support portion in a plan view.

In an embodiment, the second support unit may further include a driver driving the main support portion to be rotated, where the driver may not drive the sub-support portion.

According to an embodiment, a bonding apparatus for a display apparatus includes a first support unit on which a first panel is mounted and a second support unit on which a second panel which is bonded to the first panel is mounted, wherein the second support unit includes a stage on which the second panel is mounted, a main support portion arranged below the stage and supporting the stage, a sub-support portion connected below the stage and arranged to be spaced apart from the main support portion, and a base plate supporting the main support portion and the sub-support portion, wherein as the sub-support portion slidingly moves on a plane which is perpendicular to a rotation axis of the main support portion, the stage connected to the sub-support portion is rotated with respect to the main support portion.

In an embodiment, the main support portion and the sub-support portion may be arranged to be spaced apart from each other by a first distance, and while the stage is being rotated, the first distance between the main support portion and the sub-support portion may be maintained to be constant.

In an embodiment and in a plan view, as the sub-support portion linearly moves in a first direction and a second direction crossing the first direction on the plane which is perpendicular to the rotation axis, the stage may be rotated.

In an embodiment, the sub-support portion may include a first linear movement portion arranged on the base plate and linearly moving in the first direction, a connection plate connected above the first linear movement portion, and a second linear movement portion arranged on the connection plate and linearly moving in the second direction.

In an embodiment and in a plan view, as the sub-support portion performs a curve motion with respect to the main support portion, the stage may be rotated.

In an embodiment, the sub-support portion may include a curvature movement portion arranged on the base plate and having a curved shape and a connection plate connected above the curvature movement portion.

In an embodiment, the sub-support portion may be provided in plural and may be arranged at each of both sides of the main support portion in a plan view.

In an embodiment, the sub-support portion may be provided in plural and may be arranged at each of an upper side, a lower side, a right side, and a left side of the main support portion in a plan view.

In an embodiment, the second support unit may further include a driver driving the sub-support portion to linearly move the sub-support portion, where the driver may not drive the main support portion.

According to an embodiment, a method of manufacturing a display apparatus comprises arranging a first panel on a first support unit, arranging a second panel on a second support unit, correcting a shaft rotation of the second support unit for the alignment of the second panel, and pressing the first panel above the second support unit to bond the first panel to the second panel while a portion of the first panel is disposed on the second support unit to overlap the second panel, wherein the second support unit comprises a stage on which the second panel is mounted, a main support portion arranged below the stage, and a sub-support portion connected below the stage, wherein the correcting of the shaft rotation comprises a step in which the stage is rotated with the main support portion as a rotation axis as the main support portion is rotated, and the sub-support portion slidingly moves on a plane directed perpendicular to the rotation axis as the stage rotated.

According to an embodiment, a method of manufacturing a electronic device comprises manufacturing a display apparatus and accommodating the display apparatus in the housing, wherein manufacturing the display apparatus comprises arranging a first panel on a first support unit, arranging a second panel on a second support unit, correcting a shaft rotation of the second support unit for the alignment of the second panel, and pressing the first panel above the second support unit to bond the first panel to the second panel while a portion of the first panel is disposed on the second support unit to overlap the second panel, wherein the second support unit comprises a stage on which the second panel is mounted, a main support portion arranged below the stage, and a sub-support portion connected below the stage, wherein the correcting of the shaft rotation comprises a step in which the stage is rotated with the main support portion as a rotation axis as the main support portion is rotated, and the sub-support portion slidingly moves on a plane directed perpendicular to the rotation axis as the stage rotated.

### BRIEF DESCRIPTION OF THE DRAWINGS

The above and other aspects, features, and advantages of certain embodiments of the invention will be more apparent from the following description taken in conjunction with the accompanying drawings, in which:

FIG. 1 is a schematic plan view of a portion of a display apparatus showing a display panel in an unbent state, according to an embodiment;

FIG. 2 is a schematic lateral cross-sectional view of a portion of a display apparatus showing a display panel in a bent state, according to an embodiment;

FIG. 3 is a schematic equivalent circuit diagram of a pixel circuit applicable to a display apparatus, according to an embodiment;

FIG. 4 is a schematic cross-sectional view of a portion of a display apparatus of FIG. 1 taken along line A-A′, according to an embodiment;

FIG. 5 is a schematic cross-sectional view of a bonding apparatus for a display apparatus, according to an embodiment;

FIG. 6 is a schematic front view of a second support unit, wherein a first support unit is omitted, according to an embodiment;

FIG. 7 is a schematic plan view of a second support unit illustrating a main support portion and a sub-support portion, wherein a first support unit is omitted, according to an embodiment; and

FIG. 8 is a schematic plan view of a second support unit which is substantially the same as FIG. 7, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

While the invention is capable of various modifications and alternative forms, embodiments thereof are shown by way of example in the drawings and will herein be described in detail. Effects and characteristics of the invention and methods of achieving the same will become apparent by referring to the embodiments described in detail below along with the drawings. However, the invention is not limited to the embodiments disclosed hereinafter and may be realized in various forms.

Hereinafter, embodiments will be described in detail by referring to the accompanying drawings, wherein, when describing the accompanying drawings, elements that are the same as or corresponding to each other will be assigned the same reference numerals, repeated descriptions thereof will not be given.

It will be understood that although the terms “first,” “second,” etc. may be used herein to describe various components, these components should not be limited by these terms. These components are only used to distinguish one component from another.

As used herein, the singular expressions “a,” “an,” and “the” are intended to include the plural forms as well, unless the context clearly indicates otherwise.

It will be further understood that the terms “comprises” and/or “comprising” used herein specify the presence of stated features or elements, but do not preclude the presence or addition of one or more other features or elements.

It will be further understood that when a layer, region, or element is referred to as being formed “on” another layer, area, or element, it can be directly or indirectly formed on the other layer, region, or element. That is, for example, intervening layers, regions, or elements may be present.

Sizes of elements in the drawings may be exaggerated for convenience of explanation. For example, sizes and thicknesses of the elements in the drawings are randomly indicated for convenience of explanation, and thus, the invention is not necessarily limited to the illustrations of the drawings.

In the embodiments hereinafter, the x-axis, the y-axis and the z-axis are not limited to three axes of the rectangular coordinate system and may be interpreted in a broader sense. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

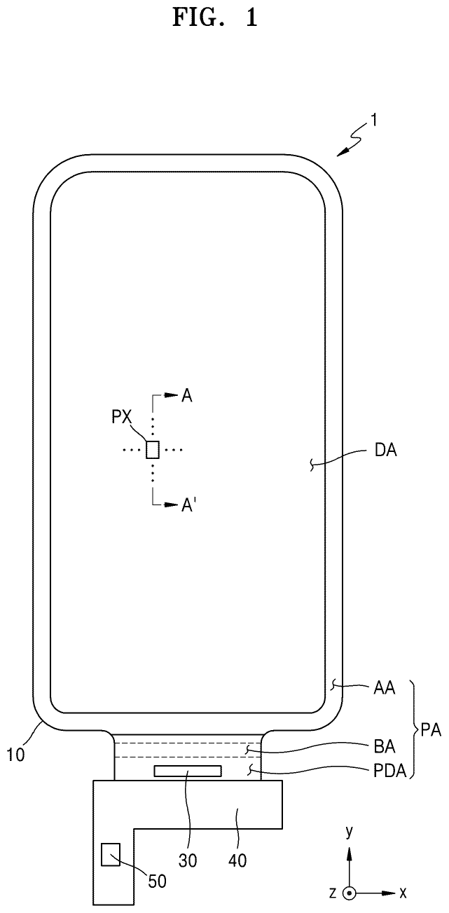

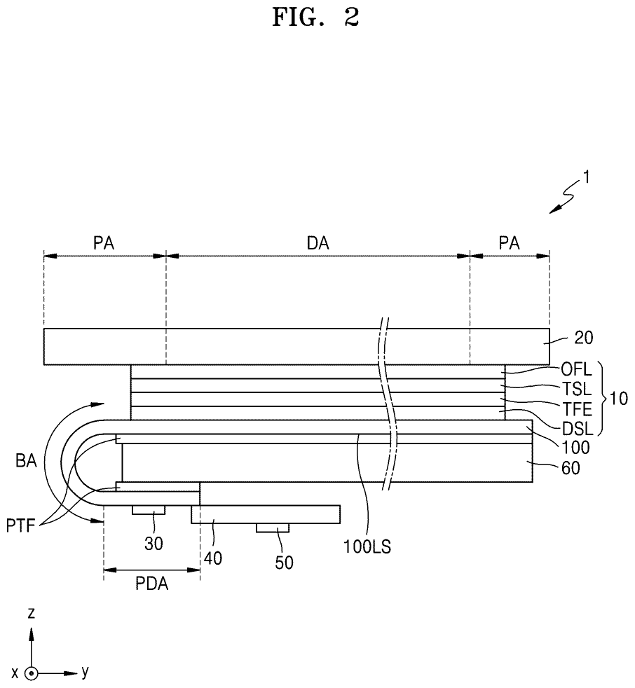

FIG. 1 is a schematic plan view of a portion of a display apparatus 1, according to an embodiment, and shows a display panel 10 in an unbent state for convenience of explanation. FIG. 2 is a schematic lateral cross-sectional view of a portion of the display apparatus 1, according to an embodiment, and shows the display panel 10 in a bent state.

In an embodiment and referring to FIGS. 1 and 2, the display apparatus 1 may display a motion image or a static image and may be used as a display screen not only of portable electronic devices, such as a mobile phone, a smartphone, a tablet personal computer (PC), a mobile communication terminal, an electronic notebook, an electronic book, a portable multimedia player (PMP), a navigation device, and an ultra-mobile PC (UMPC), but also of various products, such as a television (TV), a notebook computer, a monitor, a signboard, an Internet of things (IOT) device, etc. Also, the display apparatus 1, according to an embodiment, may be used for wearable devices, such as a smart watch, a watch phone, a glasses-type display, and a head-mounted display (HMD). Also, the display apparatus 1, according to an embodiment, may be used as a center information display (CID) on a gauge of a vehicle or a center fascia or a dashboard of a vehicle, a room mirror display substituting a side-view mirror of a vehicle or a display arranged on a rear surface of a front seat, as an entertainment device for a backseat of a vehicle.

In an embodiment, the display apparatus 1 may be accommodated in a housing of the electronic device. The housing may serve as a cover that protects internal components such as the display apparatus 1 and forms an exterior of the electronic device. In addition, the display apparatus 1 may be connected to an electronic module of the electronic device and may be driven on the electronic device. Hereinafter, the explanation will focus on the display apparatus 1.

In an embodiment and as illustrated in FIG. 1, the display apparatus 1 may approximately have a rectangular shape. For example, as illustrated in FIG. 1, the display apparatus 1 may generally have a rectangular planar shape having a short side extending in a first direction (for example, an x direction or a −x direction) and a long side extending in a second direction (for example, a y direction or a −y direction). According to an embodiment, a portion of the display apparatus 1, at which the short side extending in the first direction (for example, the x direction or the −x direction) and the long side extending in the second direction (for example, the y direction or the −y direction) meet each other, may have a rectangular shape or a circular shape having a certain curvature. However, the display apparatus 1 is not limited to the rectangular planar shape and may include other planar shapes, such as a polygonal planar shape, a circular planar shape, or an elliptical planar shape.

The display apparatus 1 may include a display area DA and a peripheral area PA, where the display area DA may display an image. Here, pixels PX may be arranged in the display area DA. The display apparatus 1 may provide an image by using light emitted from the pixels PX, where each pixel PX may emit light by using a display element. According to an embodiment, each pixel PX may emit red, green, or blue light. According to another embodiment, each pixel PX may emit red, green, blue, or white light.

In an embodiment, the peripheral area PA may be a non-display area which does not display an image. The peripheral area PA may at least partially surround the display area DA. For example, the peripheral area PA may entirely surround the display area DA. A driver configured to provide electrical signals to the pixels PX and power lines configured to provide a power supply, or the like may be arranged in the peripheral area PA. For example, a scan driver configured to apply scan signals to the pixels PX may be arranged in the peripheral area PA. Also, a data driver configured to apply data signals to the pixels PX may be arranged in the peripheral area PA. According to an embodiment, the peripheral area PA may include an adjacent area AA disposed adjacent to the display area DA and surrounding the display area DA, a bending area BA connected to a side of the adjacent area AA and capable of being bent, and a pad area PDA to which the bending area BA is connected and in which pads are arranged.

In an embodiment and referring to FIG. 2, the display apparatus 1 may include the display panel 10, a cover window 20, a display driver 30, a display circuit board 40, a touch sensor driver 50, a cover panel 60, and a protective film PTF.

The display panel 10 may display information processed by the display apparatus 1. For example, the display panel 10 may display execution screen information of an application driven by the display apparatus 1 or the display panel 10 may display user interface (UI) or graphics user interface (GUI) information based on the execution screen information.

The display panel 10 may include a display element. For example, the display panel 10 may include an organic light-emitting display panel using an organic light-emitting diode, a micro light-emitting diode display panel using a micro light-emitting diode, a quantum-dot light-emitting display panel using a quantum-dot light-emitting diode including a quantum-dot emission layer, or an inorganic light-emitting display panel using an inorganic light-emitting diode including an inorganic semiconductor. Hereinafter, an embodiment where the display panel 10 includes an organic light-emitting display panel using an organic light-emitting diode as a display element will be mainly described in detail.

In an embodiment, the display panel 10 may include a substrate 100 and multiple layers disposed on the substrate 100. According to an embodiment, the display panel 10 may include the substrate 100, a display layer DSL, an encapsulation layer TFE, a touch sensor layer TSL, and an optical functional layer OFL. Here, the display area DA and the peripheral area PA may be defined in the substrate 100 and/or the multiple layers. For example, the substrate 100 may include the display area DA and the peripheral area PA. Also, the peripheral area PA may include the pad area PDA and the bending area BA.

In an embodiment, the substrate 100 may include polymer resins, such as polyethersulfone, polyarylate, polyetherimide, polyethylene naphthalate, polyethylene terephthalate, polyphenylene sulfide, polyimide, polycarbonate, cellulose tri acetate, or cellulose acetate propionate. According to an embodiment, the substrate 100 may have a multi-layered structure including a base layer including the polymer resins described above and a barrier layer (not shown). The substrate 100 including the polymer resins may be flexible, rollable, or bendable.

In an embodiment, the substrate 100 may be bent in the bending area BA. In this case, according to an embodiment, the substrate 100 may be bent in the bending area BA to have a “U” shape, so that at least portions of a lower surface 100LS of the substrate 100 may face each other, and the pad area PDA of the substrate 100 may be positioned below other portions of the substrate 100. Thus, an area of the peripheral area PA, the area which is visible to a user, may be reduced. FIG. 2 illustrates that only the substrate 100 is bent. However, according to another embodiment, at least a portion of the display layer DSL, at least a portion of the encapsulation layer TFE, and at least a portion of the touch sensor layer TSL may also correspond to the bending area BA and the pad area PDA. In this case, the at least the portion of the display layer DSL, the at least the portion of the encapsulation layer TFE, and the at least the portion of the touch sensor layer TSL may also be bent in the bending area BA.

In an embodiment, the display layer DSL may be disposed on the substrate 100 and may include pixel circuits and display elements. Here, the pixel circuits may be connected to the display elements, respectively. The pixel circuit may include a transistor and a storage capacitor. Thus, the display layer DSL may include the plurality of display elements, a plurality of transistors, and storage capacitors. Also, the display layer DSL may further include insulating layers which are disposed between the plurality of display elements, the plurality of transistors, and the storage capacitors.

In an embodiment, the encapsulation layer TFE may be disposed on the display layer DSL, where the encapsulation layer TFE may be disposed on the display element and may cover the display element. According to an embodiment, the encapsulation layer TFE may include at least one inorganic encapsulation layer and at least one organic encapsulation layer. The at least one inorganic encapsulation layer may include one or more inorganic materials from among Al₂O₃, TiO₂, Ta₂O₅, ZnO, SiO₂, SiNₓ, and SiON. The at least one organic encapsulation layer may include a polymer-based material. The polymer-based material may include acryl-based resins, epoxy-based resins, polyimide, polyethylene, etc. According to an embodiment, the at least one organic encapsulation layer may include acrylate.

In an embodiment, the touch sensor layer TSL may be disposed on the encapsulation layer TFE, where the touch sensor layer TSL may sense coordinate information according an external input, for example, a touch event. The touch sensor layer TSL may include a sensor electrode and touch lines connected to the sensor electrode. The touch sensor layer TSL may sense an external input according to a magnetic capacitance method or a mutual capacitance method.

In an embodiment, the touch sensor layer TSL may be formed on the encapsulation layer TFE. In another embodiment, after the touch sensor layer TSL may be separately formed on a touch substrate, the touch sensor layer TSL may be attached onto the encapsulation layer TFE through an adhesive layer, such as an optically clear adhesive. According to an embodiment, the touch screen layer TSL may be formed directly on the encapsulation layer TFE, and in this case, the adhesive layer may not be disposed between the touch sensor layer TSL and the encapsulation layer TFE.

In an embodiment, the optical functional layer OFL may be disposed on the touch sensor layer TSL and may reduce the reflectivity of light (external light) which may be incident from the outside toward the display apparatus 1 and/or improve the color purity of light which is emitted from the display apparatus 1. According to an embodiment, the optical functional layer OFL may include a phase retarder and a polarizer. The phase retarder may include a film-type phase retarder or a liquid crystal coating-type phase retarder, and may include a λ/2 phase retarder and/or a λ/4 phase retarder. The polarizer may also include a film-type polarizer or a liquid crystal coating-type polarizer. The film-type polarizer may include an elongation-type synthetic resin film, and the liquid crystal coating-type polarizer may include liquid crystals arranged in a certain shape. The phase retarder and the polarizer may further include a protective film.

According to another embodiment, the optical functional layer OFL may include a black matrix and color filters, where the color filters may be arranged by taking into account a color of the light emitted from each pixel in the display apparatus 1. Each color filter may include a red, green, or blue pigment or dye. In another embodiment, each color filter may further include quantum dots, in addition to the pigment or the dye described above. In still another embodiment, some of the color filters may not include the pigment or the dye described above and may include scattered particles, such as oxide titanium.

According to another embodiment, the optical functional layer OFL may include a destructive interference structure, where the destructive interference structure may include a first reflective layer and a second reflective layer disposed on different layers. First reflective light and second reflective light reflected from the first reflective layer and the second reflective layer, respectively, may destructively interfere, and thus, the reflectivity of external light may be decreased.

In an embodiment, the cover window 20 may be disposed on the display panel 10 and may protect the display panel 10. According to an embodiment, the cover window 20 may include a flexible window. The cover window 20 may protect the display panel 10 by being easily bent through an external force without the occurrence of cracks, etc. The cover window 20 may include at least one of glass, sapphire, and plastic. The cover window 20 may include, for example, ultra-thin glass (UTG) or colorless polyimide (CPI). According to an embodiment, the cover window 20 may have a structure in which a flexible polymer layer is disposed on a surface of a glass substrate or may have a structure including only a polymer layer.

In an embodiment, the cover window 20 may be attached onto the display panel 10 through an adhesive member, where the adhesive member may include a transparent adhesive member such as an optically clear adhesive (OCA). In addition, the adhesive member may include various other well-known adhesive materials. The adhesive member may be attached above the display panel 10 as a type of film, or a type of material may be spread above the display panel 10 as the adhesive member. As such, the adhesive member may be formed above the display panel 10 in various ways.

In an embodiment, the display driver 30 may be arranged in the pad area PDA and may receive control signals and power voltages and may generate and output signals and voltages for driving the display panel 10. The display driver 30 may include an integrated circuit (IC).

In an embodiment, the display circuit board 40 may be electrically connected to the display panel 10. For example, the display circuit board 40 may be electrically connected to the pad area PDA of the substrate 100 by an anisotropic conductive film.

The display circuit board 40 may include a flexible printed circuit board (FPCB) which may be a bent or a rigid printed circuit board (PCB) which is rigid and not easily bent. In another embodiment, the display circuit board 40 may include a complex printed circuit board including both a PCB and an FPCB.

In an embodiment, the touch sensor driver 50 may be disposed on the display circuit board 40 and may include an IC. The touch sensor driver 50 may be attached to the display circuit board 40. The touch sensor driver 50 may be electrically connected to sensor electrodes of the touch sensor layer TSL of the display panel 10 through the display circuit board 40.

However, in addition thereto, a power supply portion may further be disposed on the display circuit board 40, where the power supply portion may supply a driving voltage for driving the pixels of the display panel 10 and the display driver 30.

In an embodiment, the protective film PTF may be patterned and attached onto the lower surface 100LS of the substrate 100, where the protective film PTF may be attached onto areas of the substrate 100 with the exception of the bending area BA. Here, a portion of the protective film PTF may be disposed on the opposite side of the display layer DSL with the substrate 100 disposed therebetween. Another portion of the protective film PTF may be attached onto the lower surface 100LS of the substrate 100 to correspond to the pad area PDA.

According to an embodiment, the cover panel 60 may be disposed between the portions of the protective film PTF. In other words, the cover panel 60 may be disposed between a portion (for example, a first portion) and another portion (for example, a second portion) of the substrate 100 that face each other as the substrate 100 is bent to have the “U” shape. The cover panel 60 may absorb external shocks to prevent the fracture of the display panel 10.

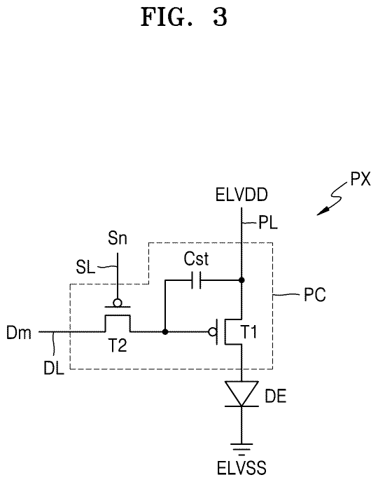

FIG. 3 is a schematic equivalent circuit diagram of a pixel circuit PC applicable to a display apparatus, according to an embodiment.

In an embodiment and referring to FIG. 3, the pixel circuit PC may be electrically connected to a display element DE and may include a first transistor T1, a second transistor T2, and a storage capacitor Cst. According to an embodiment, the display element DE may emit red, green, or blue light or red, green, blue, or white light.

In an embodiment, the second transistor T2 may be connected to a scan line SL and a data line DL and may be configured to transmit, to the first transistor T1, a data signal or a data voltage which is input from the data line DL, in response to a scan signal or a switching voltage which is input from the scan line SL.

In an embodiment, the storage capacitor Cst may be connected to the second transistor T2 and a driving voltage line PL and may be configured to store a voltage corresponding to a difference between a voltage received from the second transistor T2 and a first power voltage ELVDD supplied to the driving voltage line PL.

In an embodiment, the first transistor T1 may be connected to the driving voltage line PL and the storage capacitor Cst and may be configured to control a driving current flowing from the driving voltage line PL through the display element DE according to a value of the voltage stored in the storage capacitor Cst. The display element DE may emit light having a certain brightness according to the driving current. An opposite electrode of the display element DE may receive a second power voltage ELVSS.

FIG. 3 illustrates that the pixel circuit PC may include two transistors and one storage capacitor. However, in other embodiments, the pixel circuit PC may include more transistors and/or more storage capacitors than the transistors and/or the storage capacitors illustrated in FIG. 3.

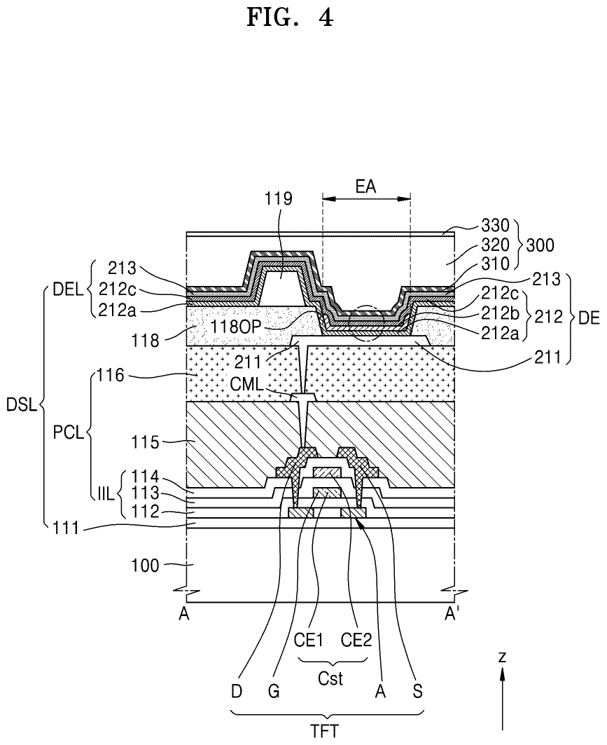

FIG. 4 is a schematic cross-sectional view of a portion of the display apparatus 1 of FIG. 1 taken along line A-A′ in FIG. 1, according to an embodiment.

In an embodiment and referring to FIG. 4, the display apparatus 1 may include the display panel 10. The display panel 10 may include the substrate 100, the display layer DSL, an encapsulation layer 300, the touch sensor layer TSL, and the optical functional layer OFL. For convenience of explanation, in the illustration of FIG. 4, the touch sensor layer TSL and the optical functional layer OFL are omitted.

In an embodiment, the display layer DSL may be disposed on the substrate 100 and may include a buffer layer 111, a pixel circuit layer PCL, and a display element layer DEL.

The substrate 100 may include glass or may include polymer resins such as polyethersulfone, polyarylate, polyetherimide, polyethylene naphthalate, polyethylene terephthalate, polyphenylene sulfide, polyimide, polycarbonate, cellulose tri acetate, or cellulose acetate propionate. The substrate 100 including the polymer resins may be flexible, rollable, or bendable. The substrate 100 may have a multi-layered structure including a base layer including the polymer resins described above and a barrier layer (not shown).

In an embodiment, the buffer layer 111 may include an inorganic insulating material, such as SiNₓ, SiON, and SiO₂, and may include a single layer or layers including the inorganic insulating material described above.

In an embodiment, the pixel circuit layer PCL may be disposed on the buffer layer 111 and may include a transistor TFT included in a pixel circuit, and an inorganic insulating layer IIL, a first planarization layer 115, and a second planarization layer 116 disposed below or/and above components of the transistor TFT. The inorganic insulating layer IIL may include a first gate insulating layer 112, a second gate insulating layer 113, and an interlayer insulating layer 114.

In an embodiment, the transistor TFT may include a semiconductor layer A, and the semiconductor layer A may include polysilicon. In another embodiment, the semiconductor layer A may include amorphous silicon, an oxide semiconductor, or an organic semiconductor. The semiconductor layer A may include a channel area, a drain area and a source area arranged at both sides of the channel area, respectively. A gate electrode G may overlap the channel area.

In an embodiment, the gate electrode G may include a low-resistance metal material. The gate electrode G may include a conductive material including Mo, Al, Cu, Ti, etc. and may include layers or a single layer including the conductive material described above.

In an embodiment, the first gate insulating layer 112 disposed between the semiconductor layer A and the gate electrode G may include an inorganic insulating material, such as SiO₂, SiNₓ, SiON, Al₂O₃, TiO₂, Ta₂O₅, HfO₂, ZnOₓ, or the like. ZnOₓ may include ZnO and/or ZnO₂.

In an embodiment, the second gate insulating layer 113 may be provided to cover the gate electrode G. Similarly to the first gate insulating layer 112, the second gate insulating layer 113 may include an inorganic insulating material, such as SiO₂, SiNₓ, SiON, Al₂O₃, TiO₂, Ta₂O₅, HfO₂, ZnOₓ, or the like. ZnOₓ may include ZnO and/or ZnO₂.

In an embodiment, an upper electrode CE2 of a storage capacitor Cst may be disposed above the second gate insulating layer 113, where the upper electrode CE2 may overlap the gate electrode G there-below. Here, the gate electrode G and the upper electrode CE2 overlapping each other with the second gate insulating layer 113 disposed therebetween may form the storage capacitor Cst of the pixel circuit. That is, the gate electrode G may function as a lower electrode CE1 of the storage capacitor Cst. As described above, the storage capacitor Cst and the transistor TFT may be formed to overlap each other. According to some embodiments, the storage capacitor Cst may not be formed to overlap the transistor TFT.

In an embodiment, the upper electrode CE2 may include Al, Pt, Pd, Ag, Mg, Au, Ni, Nd, Ir, Cr, Ca, Mo, Ti, W, and/or Cu and may include a single layer or layers including the material described above.

In an embodiment, the interlayer insulating layer 114 may cover the upper electrode CE2. The interlayer insulating layer 114 may include SiO₂, SiNₓ, SiON, Al₂O₃, TiO₂, Ta₂O₅, HfO₂, ZnOₓ, or the like. ZnOₓ may include ZnO and/or ZnO₂. The interlayer insulating layer 114 may include a single layer or layers including the inorganic insulating material described above.

In an embodiment, each of a drain electrode D and a source electrode S may be disposed on the interlayer insulating layer 114, where the drain electrode D and the source electrode S may include a highly conductive material. The drain electrode D and the source electrode S may include a conductive material including Mo, Al, Cu, Ti, etc. and may include layers or a single layer including the material described above. According to an embodiment, the drain electrode D and the source electrode S may have a layered structure of Ti/Al/Ti layers.

In an embodiment, the first planarization layer 115 may be disposed to cover the drain electrode D and the source electrode S, where the first planarization layer 115 may include an organic insulating layer. The first planarization layer 115 may include an organic insulating material, such as a general-purpose polymer such as polymethylmethacrylate (PMMA) or polystyrene (PS), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, and a blend thereof.

In an embodiment, a connection electrode CML may be disposed on the first planarization layer 115. Here, the connection electrode CML may be connected to the drain electrode D or the source electrode S through a contact hole of the first planarization layer 115. The connection electrode CML may include a highly conductive material. The connection electrode CML may include a conductive material including Mo, Al, Cu, Ti, etc. and may include layers or a single layer including the conductive material described above. According to an embodiment, the connection electrode CML may have a layered structure of Ti/Al/Ti.

In an embodiment, the second planarization layer 116 may be disposed to cover the connection electrode CML. The second planarization layer 116 may include an organic insulating layer. The second planarization layer 116 may include an organic insulating material, such as a general-purpose polymer such as PMMA or PS, a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, and a blend thereof.

In an embodiment, the display element layer DEL may be disposed on the pixel circuit layer PCL and may include a display element DE. The display element DE may include an organic light-emitting diode OLED. A pixel electrode 211 of the display element DE may be electrically connected to the connection electrode CML through a contact hole of the second planarization layer 116.

In an embodiment, the pixel electrode 211 may include conductive oxide, such as indium tin oxide (ITO), indium zinc oxide (IZO), zinc oxide (ZnO), indium oxide (In₂O₃), indium gallium oxide (IGO), or aluminum zinc oxide (AZO). According to another embodiment, the pixel electrode 211 may include a reflective layer including Ag, Mg, Al, Pt, Pd, Au, Ni, Nd, Ir, Cr, or a compound thereof. According to still another embodiment, the pixel electrode 211 may further include a layer including ITO, IZO, ZnO, or In₂O₃ above/below the reflective layer described above.

In an embodiment, a pixel-defining layer 118 having an opening 118OP exposing a central portion of the pixel electrode 211 may be disposed on the pixel electrode 211. The pixel-defining layer 118 may include an organic insulating material and/or an inorganic insulating material. The opening 118OP may define an emission area (hereinafter, referred to as an emission area EA) of light emitted from the display element DE. For example, a width of the opening 118OP may correspond to a width of the emission area EA of the display element DE.

In an embodiment, a spacer 119 may be disposed on the pixel-defining layer 118, where the spacer 119 may be provided to prevent the fracture of the substrate 100 according to a method of manufacturing the display apparatus. In a manufacturing process of the display panel, a mask sheet may be used. Here, a portion of the substrate 100 may be damaged or fractured due to the mask sheet, which is inserted into the opening 118OP of the pixel-defining layer 118 or which is made to adhere to the pixel-defining layer 118 when a deposition material is deposited on the substrate 100. The spacer 119 may prevent this damage or fracture.

In an embodiment, the spacer 119 may include an organic insulating material, such as polyimide. In another embodiment, the spacer 119 may include an inorganic insulating material, such as SiNx or SiO2, or may include an organic insulating material and an inorganic insulating material.

According to an embodiment, the spacer 119 may include a material which is different from the material of the pixel-defining layer 118. In another embodiment, the spacer 119 may include a material which is the same as the material of the pixel-defining layer 118, and in this case, the pixel-defining layer 118 and the spacer 119 may be formed together by a mask process using a halftone mask, etc.

In an embodiment, an intermediate layer 212 may be disposed on the pixel-defining layer 118, where the intermediate layer 212 may include an emission layer 212b disposed in the opening 118OP of the pixel-defining layer 118. The emission layer 212b may include a high molecular-weight or a low molecular-weight organic material emitting a certain color of light.

In an embodiment, a first functional layer 212a and a second functional layer 212c may be disposed below and above the emission layer 212b, respectively. The first functional layer 212a may include, for example, a hole transport layer (HTL), or an HTL and a hole injection layer (HIL). The second functional layer 212c may be arranged above the emission layer 212b and may be optionally arranged. The second functional layer 212c may include an electron transport layer (ETL) and/or an electron injection layer (EIL). The first functional layer 212a and/or the second functional layer 212c may be a common layer formed to entirely cover the substrate 100, like an opposite electrode 213 to be described below.

In an embodiment, the opposite electrode 213 may include a conductive material having a low work function. For example, the opposite electrode 213 may include a (semi) transparent layer including Ag, Mg, Al, Pt, Pd, Au, Ni, Nd, Ir, Cr, Li, Ca, or an alloy thereof. In another embodiment, the opposite electrode 213 may further include a layer including ITO, IZO, ZnO, or In₂O₃ on the (semi) transparent layer including the material described above.

According to some embodiments, a capping layer (not shown) may further be disposed on the opposite electrode 213, where the capping layer may include LiF, an inorganic material, or/and an organic material.

In an embodiment, the encapsulation layer 300 may be disposed on the opposite electrode 213. The encapsulation layer 300 may be disposed on the display element layer DEL and may cover the display element layer DEL. The encapsulation layer 300 may include at least one inorganic encapsulation layer and at least one organic encapsulation layer. According to an embodiment, FIG. 4 illustrates that the encapsulation layer 300 may include a first inorganic encapsulation layer 310, an organic encapsulation layer 320, and a second inorganic encapsulation layer 330 which are sequentially stacked.

In an embodiment, the first inorganic encapsulation layer 310 and the second inorganic encapsulation layer 330 may include at least one inorganic material from among aluminum oxide, titanium oxide, tantalum oxide, hafnium oxide, ZnO, SiOx, SiNx, and SiON. The organic encapsulation layer 320 may include a polymer-based material. The polymer-based material may include acryl-based resins, epoxy-based resins, polyimide, polyethylene, etc. According to an embodiment, the organic encapsulation layer 320 may include acrylate. The organic encapsulation layer 320 may be formed by curing a monomer or by being coated with a polymer. The organic encapsulation layer 320 may be transparent.

Although not shown, in an embodiment, the touch sensor layer described above may be disposed on the encapsulation layer 300, and the optical functional layer may be disposed on the touch sensor layer.

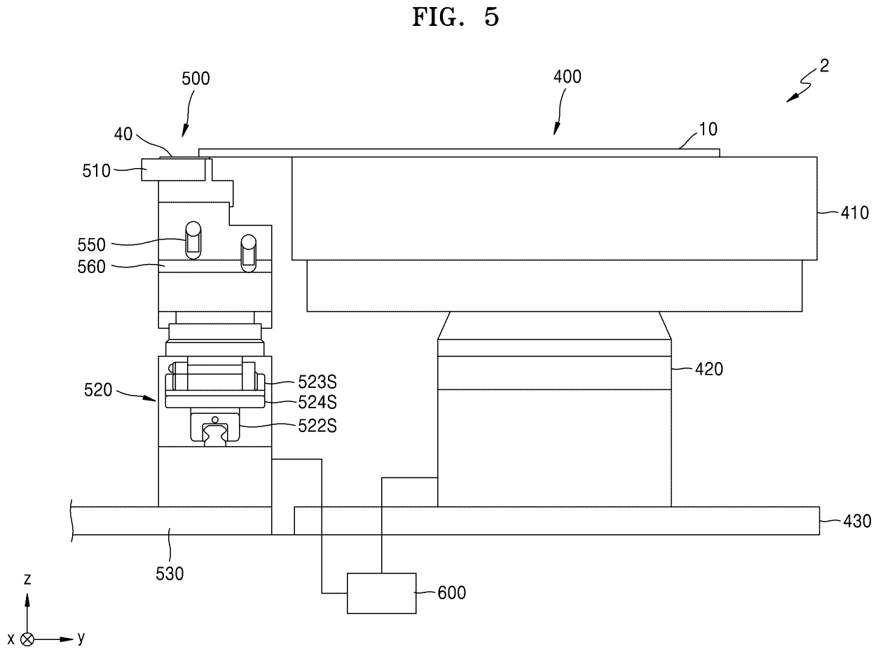

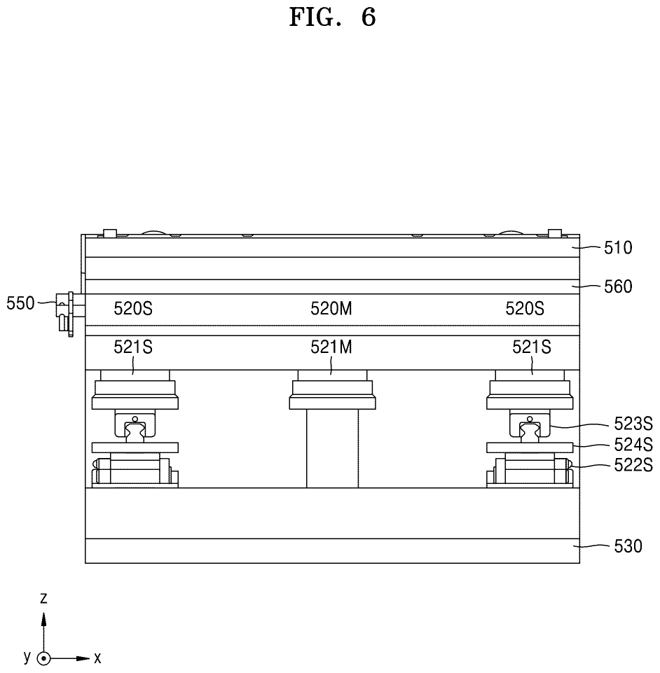

FIG. 5 is a schematic cross-sectional view of a bonding apparatus 2 for the display apparatus 1, according to an embodiment. According to an embodiment, the bonding apparatus 2 for the display apparatus 1 may be used to bond the components of the display apparatus 1 described above. FIG. 6 is a schematic front view of a second support unit 500, according to an embodiment. In FIG. 6, a first support unit 400 is omitted, for convenience of explanation.

In an embodiment and referring to FIG. 5, the bonding apparatus 2 for the display apparatus 1 may be used to bond the components of the display apparatus 1, for example, the display panel 10 and the display circuit board 40. According to an embodiment, the bonding apparatus 2 for the display apparatus 1 may include the first support unit 400 and the second support unit 500.

In an embodiment, the first support unit 400 may support a first panel and the second support unit 500 may support a second panel. Also, to bond the first panel and the second panel to each other, a portion of the first panel may be disposed on the second support unit 500 to overlap the second panel. Next, a pressing unit (not shown) may press the first panel above the second support unit 500 to bond the first panel to the second panel. Here, a pressing weight may be mostly concentrated in the second support unit 500. Hereinafter, the first support unit 400 and the second support unit 500 will be described in detail.

In an embodiment, the first support unit 400 may support the first panel, for example, the display panel 10. Hereinafter, an embodiment where the first panel is the display panel 10 is mainly described. The display panel 10 may be mounted on a first stage 410. According to an embodiment, the first stage 410 may have a quadrangular cross-section having a long side extending in a first direction (for example, an x direction of FIG. 5) and a short side extending in a second direction (for example, a y direction of FIG. 5) crossing the first direction. However, the first stage 410 may have the short side extending in the first direction and the long side extending in the second direction or may have a square cross-section having the sides having the same length. Accordingly, the first stage 410 may have an xy-planar surface, and the display panel 10 may be mounted on the first stage 410.

In an embodiment, a first cylinder 420 may be connected below the first stage 410. The first cylinder 420 may function as a support shaft supporting the first stage 410 and may be connected to a first base plate 430. The first cylinder 420 may extend in a third direction (for example, a z direction of FIG. 5) and may be arranged between the first stage 410 and the first base plate 430. According to an embodiment, the first cylinder 420 may be spun or rotated. Here, that the first cylinder 420 is spun may denote that the first cylinder 420 is rotated with respect to a rotational axis in the same direction (the z direction) as the extension direction of the first cylinder 420, where the rotational axis is positioned in the center of the first cylinder 420. Here, a driver 600 may be connected to the first cylinder 420, and the driver 600 may drive the first cylinder 420 to be rotated. The driver 600 may be located in the first cylinder 420. However, the driver 600 is not limited thereto. The driver 600 may be located outside the first cylinder 420 and may be electrically connected to the first cylinder 420. The first cylinder 420 may be spun by a certain angle in a plan view to spin and align the first stage 410 connected to the first cylinder 420. Through this alignment, the first panel and the second panel may be relatively better aligned with each other and bonded to each other.

In an embodiment and referring to FIGS. 5 and 6, the second support unit 500 may support the second panel, for example, the display circuit board 40. Hereinafter, an embodiment where the second panel is the display circuit board 40 is mainly described. The display circuit board 40 may be mounted on a second stage 510. According to an embodiment, the second stage 510 may have a quadrangular cross-section having a long side extending in the first direction (for example, the x direction of FIG. 5) and a short side extending in the second direction (for example, the y direction of FIG. 5) crossing the first direction. However, the second stage 510 may have the short side extending in the first direction and the long side extending in the second direction or may have a square cross-section having the sides having the same length. Accordingly, the second stage 510 may have an xy-planar surface, and the display circuit board 40 may be mounted on the second stage 510.

In an embodiment, support portions 520 may be arranged below the second stage 510 to support the second stage 510. According to an embodiment, the support portions 520 may include a main support portion 520M and a sub-support portion 520S.

In an embodiment, the main support portion 520M may be arranged below the center of the second stage 510 to support the center of the second stage 510. An upper end of the main support portion 520M may be connected to the second stage 510 and a lower end of the main support portion 520M may be connected to a second base plate 530. Also, according to an embodiment, the main support portion 520M may include a second cylinder 521M, where the second cylinder 521M may function as a support shaft supporting the second stage 510 and which may be connected to the second base plate 530. The second cylinder 521M may extend in the third direction (for example, the z direction of FIG. 5) and may be arranged between the second stage 510 and the second base plate 530. According to an embodiment, the second cylinder 521M may be rotated. It should be appreciated that the fact that the second cylinder 521M is spun may denote that the second cylinder 521M is rotated with respect to a rotational axis in the same direction (the z direction) as the extension direction of the second cylinder 521M, where the rotational axis is positioned in the center of the second cylinder 521M. According to an embodiment, the driver 600 may be connected to the second cylinder 521M, and the driver 600 may drive the second cylinder 521M to be rotated. The driver 600 may be located in the second cylinder 521M. However, the driver 600 is not limited thereto. In another embodiment, the driver 600 may be located outside the second cylinder 521M and may be electrically connected to the second cylinder 521M. The second cylinder 521M may be rotated by a certain angle in a plan view to spin and align the second stage 510 connected to the second cylinder 521M. Through this alignment, the second panel and the first panel may be relatively better aligned with each other and bonded to each other.

In an embodiment, the sub-support portion 520S may be arranged to support the second stage 510 together with the main support portion 520M. The sub-support portion 520S may be arranged at a side of the main support portion 520M. In detail, the sub-support portion 520S may be arranged at a side of the main support portion 520M in a first direction (for example, a +x direction of FIG. 6). Also, the sub-support portion 520 may include two sub-support portions 520, and in this case, the sub-support portions 520 may be arranged on two sides of the main support portion 520M in the first direction (for example, the +x direction and a −x direction of FIG. 6). According to another embodiment, the sub-support portion 520S may include more than two sub-support portions 520, and in this case, each of the plurality of sub-support portions 520S may be arranged to be distributed with respect to the main support portion 520M. For example, when the sub-support portion 520S includes four sub-support portions 520S, each of the sub-support portions 520S may be arranged at an upper side, a lower side, a right side, or a left side with respect to the main support portion 520M in a plan view. The number of sub-support portions 520S may be in relation to a size of the second stage 510. That is, as the size of the second stage 510 increases, an increased number of sub-support portions 520S may be arranged to support a distributed weight of the second stage 510 together with the main support portion 520M. Hereinafter, an embodiment where the sub-support portion 520S includes two sub-support portions as illustrated in FIG. 6 is mainly described.

According to an embodiment, the sub-support portion 520S may include a third cylinder 521S and linear movement portions. The third cylinder 521S may function as a support shaft supporting the second stage 510, where the third cylinder 521S may extend in the third direction (for example, the z direction) and may be arranged between the second stage 510 and the second base plate 530.

A first linear movement portion 522S and a second linear movement portion 523S may be arranged below the third cylinder 521S, where the first linear movement portion 522S may slidingly move in the first direction (for example, the x direction of FIG. 6). According to an embodiment, the first linear movement portion 522S may include a linear motor to slidingly move in the first direction. The first linear movement portion 522S may be fixed to the second base plate 530 there-below. That is, a guide rail of the first linear movement portion 522S may be fixed to the second base plate 530, and a movement unit of the first linear movement portion 522S may slidingly move on the guide rail.

In an embodiment, a connection plate 524S may be arranged above the first linear movement portion 522S, that is, above the movement unit of the first linear movement portion 522S. The connection plate 524S may be fixed to the movement unit of the first linear movement portion 522S and may move together with the movement unit when the movement unit moves in the first direction.

In an embodiment, the second linear movement portion 523S may be arranged on the connection plate 524S, where the second linear movement portion 523S may slidingly move on the connection plate 524S in a second direction (for example, a y direction of FIG. 6). According to an embodiment, the second linear movement portion 523S may include a linear motor to slidingly move in the second direction. The second linear movement portion 523S may be fixed to the connection plate 524S there-below. That is, a guide rail of the second linear movement portion 523S may be fixed to the connection plate 524S, and a movement unit of the second linear movement portion 523S may slidingly move on the guide rail.

In an embodiment, the third cylinder 521S may be arranged above the second linear movement portion 523S, that is, above the movement unit of the second linear movement portion 523S. The third cylinder 521S may be fixed to the movement unit of the second linear movement portion 523S and may move together with the movement unit as the movement unit moves in the second direction.

According to an embodiment, a heater 550 may further be arranged between the main support portion 520M and the sub-support portion 520S, and the second stage 510. The heater 550 may heat the second panel arranged on the second stage 510, for example, the printed circuit board 40, to a bonding temperature. Also, a heat insulation layer 560 may further be arranged to be disposed between the heater 550, and the second cylinder 521M and the third cylinder 521S. The heat insulation layer 560 may prevent the transmission of the heat, supplied by the heater 550, to the second cylinder 521M, the third cylinder 521S, and the movement portions below the second cylinder 521M and the third cylinder 521S.

Also, although not shown in the drawings, in an embodiment, an ionizer (not shown) for removing an electrostatic force in a bonding process of the first panel and the second panel may be arranged.

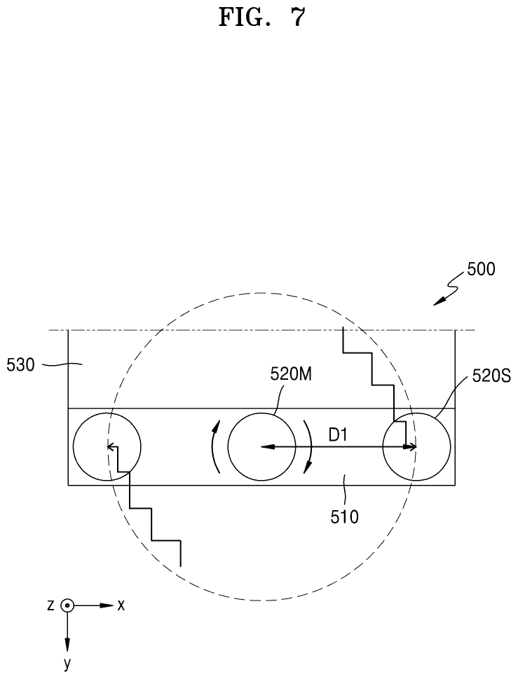

FIG. 7 is a schematic plan view of the second support unit 500, according to an embodiment. In FIG. 7, the first support unit 400 is omitted for convenience of explanation and the main support portion 520M and the sub-support portion 520S are mainly illustrated.

In an embodiment and referring to FIG. 7, in a process of bonding the first panel to the second panel, an operation of aligning the second support unit 500 to align the first panel with the second panel, is to be described. As described above, the second panel may be mounted on the second support unit 500 and the pressing unit may perform a pressing operation above the second support unit 500. Thus, according to the related art, a pressing weight by the pressing unit may be concentrated in the second support unit 500, and a deflection or pushing problem may particularly occur in the second stage 510 due to the pressing weight. According to an embodiment, the second support unit 500 may include not only the main support portion 520M but also the at least one sub-support portion 520S. Thus, the pressing weight may be distributed between the main support portion 520M and the sub-support portion 520S, where the main support portion 520M may be arranged in the center of the second stage 510 and the sub-support portion 520S may be arranged to be spaced apart from the main support portion 520M to be disposed adjacent to a circumference of the second stage 510. Thus, the second stage 510 may be stably supported and the deflection or pushing problem in the second stage 510 may be prevented.

Also, by including the plurality of support portions, the second support unit 500, according to an embodiment, may distribute the pressing weight as well as easily correcting the shaft rotation for the alignment of the second panel. In detail, the main support portion 520M may be rotated by a certain angle by the driver 600, as described above. Thus, the second stage 510 connected above the main support portion 520M may be rotated together. In this embodiment, because, in a plan view, the second stage 510 may be rotated with the main support portion 520M as a rotation axis, the second stage 510 may not be rotated when the sub-support portions 520S, which are arranged to be spaced apart from the main support portion 520M and the rotation axis, are fixed.

However, according to an embodiment, the sub-support portions 520S may include the first linear movement portion 522S slidable in a first direction (an x direction of FIG. 7) and the second linear movement portion 523S slidable in a second direction (a y direction of FIG. 7). Thus, when the main support portion 520M is rotated so that the second stage 510 is rotated with the main support portion 520M as the rotation axis, the sub-support portions 520S may, with the rotation of the second stage 510, linearly move in a first direction and a second direction on a plane which is perpendicular to the main support portion 520M which is the rotation axis. According to an embodiment, the main support portion 520M and the sub-support portion 520S may be arranged to be spaced apart from each other by a first distance D1 in the plan view. Also, when the second stage 510 is rotated by the main support portion 520M, the sub-support portion 520S may linearly move in the first direction and the second direction, and thus, the sub-support portion 520S may move by maintaining the first distance D1. In the plan view, the movement of the sub-support portion 520S may be a linear movement in the first direction and the second direction. However, the movement of the sub-support portion 520S may be substantially similar to an orbit movement having the main support portion 520M as a rotation axis.

As described above, in an embodiment, the main support portion 520M may be rotated as a fixed end, and the sub-support portion 520S may be slidingly moved due to the rotation of the second stage 510 as a free end. Therefore, the second support unit 500 may distribute the pressing weight through the plurality of support portions and may easily perform the shaft rotation correction.

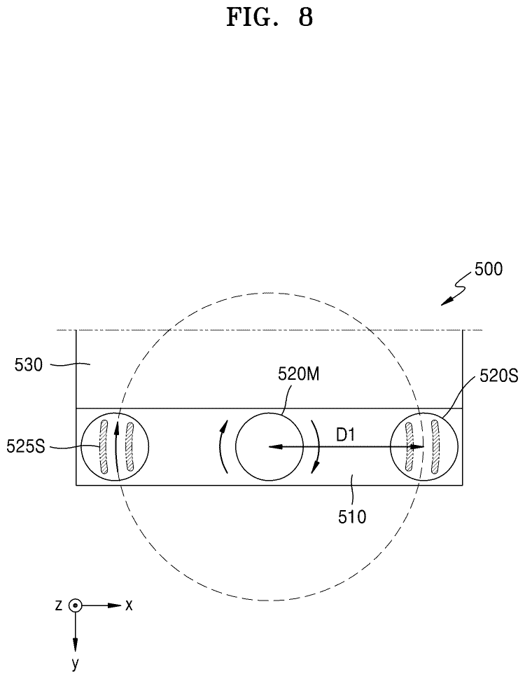

FIG. 8 is a schematic plan view of the second support unit 500, according to an embodiment and is similar to FIG. 7. The second support unit 500, according to an embodiment, described with reference to FIG. 8, may be similar to the second support unit 500 described above. Thus, hereinafter, only differences are mainly described.

In an embodiment and referring to FIG. 8, the sub-support portion 520S may include a curvature movement portion 525S disposed between the third cylinder 521S and the second base plate 530. That is, the sub-support portion 520S may include the curvature movement portion 525S rather than the first linear movement portion 522S and the second linear movement portion 523S. The curvature movement portion 525S may allow the sub-support portion 520S to perform a curved motion with respect to the main support portion 520M. In detail, a guide rail of the curvature movement portion 525S may have a curved shape having a curvature as illustrated in FIG. 8. The guide rail may extend along a portion of an arc having, as a radius, the first distance D1 between the main support portion 520M and the sub-support portion 520S. Here, a movement unit of the curvature movement portion 525S may move along this curved guide rail. In this case, the connection plate 524S may be arranged above the curvature movement portion 525S, that is, above the movement unit of the curvature movement portion 525S. The connection plate 524S may be fixed to the movement unit of the curvature movement portion 525S and may be moved together when the movement unit performs the curved motion. The third cylinder 521S may be arranged above the connection plate 524S.

In an embodiment and as described above, when the main support portion 520M is rotated so that the second stage 510 is rotated with the main support portion 520M as a rotation axis, the sub-support portion 520S connected to the second stage 510 may slidingly move along the guide rail of the curvature movement portion 525S. Thus, the second support unit 500 may distribute the pressing weight through the plurality of support portions and may easily perform shaft rotation correction.

In an embodiment, the second support unit 500 according to an embodiment is further described with reference to FIG. 7. The second support unit 500 according to an embodiment may be similar to the second support unit 500 described above. Thus, hereinafter, only differences are mainly described.

According to an embodiment, the driver 600 may be connected to the sub-support portion 520S. In detail, the first linear movement portion 522S and the second linear movement portion 523S of the sub-support portion 520S may be driven by the driver 600 to move linearly. Thus, the second stage 510 connected above the third cylinder 521S of the sub-support portion 520S may be rotated with the main support portion 520M as a rotation axis. Here, the main support portion 520M may not be driven by the driver 600 to be rotated, but may be rotated by the movement of the linear movement portions and the second stage 510. That is, for comparison, according to the embodiment of FIG. 7, the main support portion 520M may be driven by the driver 600 to be rotated so that the second stage 510 may be rotated so as to induce the linear movement of the linear movement portions. However, according to an embodiment, the linear movement portions may be driven by the driver 600 to move linearly, so that the second stage 510 may be rotated to induce the spinning of the main support portion 520M.

Also, it may be understood that when the second support unit 500 includes the curvature movement portion 525S rather than the linear movement portions, the driving operation may be similar as described above. That is, the curvature movement portion 525S may be driven by the driver 600 to perform a curved motion, and thus, the second stage 510 may be rotated with the main support portion 520M as the rotation axis.

According to an embodiment, the bonding apparatus 2 for the display apparatus 1 may support the display apparatus 1 by distributing the pressing weight exerted by the pressing unit.

Accordingly, the panels, for example, the display panel and the display circuit board, may be bonded to each other with increased precision.

Also, while the pressing weight is distributed on the supported display apparatus, shaft rotation correction of the support units to align the panels may be easily performed.

Effects of the one or more of the embodiments described above are not limited to the effects described above, and other effects that not are described may be clearly understood by one of ordinary skill in the art.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope of the invention. Moreover, the embodiments or parts of the embodiments may be combined in whole or in part without departing from the scope of the invention.

What is claimed is:

1. A bonding apparatus for a display apparatus, the bonding apparatus comprising:
a first support unit on which a first panel is mounted; and
a second support unit on which a second panel which is bonded to the first panel is mounted,
wherein the second support unit comprises:
a stage on which the second panel is mounted;
a main support portion arranged below the stage and supporting the stage, wherein as the main support portion is rotated, the stage is rotated with the main support portion as a rotation axis;
a sub-support portion connected below the stage and supporting the stage, wherein as the stage is rotated, the sub-support portion slidingly moves on a plane directed perpendicular to the rotation axis; and
a base plate supporting the main support portion and the sub-support portion.

2. The bonding apparatus of claim 1, wherein the main support portion and the sub-support portion are arranged to be spaced apart from each other by a first distance, and while the stage is being rotated, the first distance between the main support portion and the sub-support portion is constant.

3. The bonding apparatus of claim 1, wherein, in a plan view, as the stage is rotated, the sub-support portion linearly moves in a first direction and a second direction crossing the first direction on the plane.

4. The bonding apparatus of claim 3, wherein the sub-support portion comprises:
a first linear movement portion arranged on the base plate and linearly moving in the first direction;
a connection plate connected above the first linear movement portion; and
a second linear movement portion arranged on the connection plate and linearly moving in the second direction.

5. The bonding apparatus of claim 1, wherein, in a plan view, as the main support portion is rotated, the sub-support portion performs a curve motion with respect to the main support portion.

6. The bonding apparatus of claim 5, wherein the sub-support portion comprises:
a curvature movement portion arranged on the base plate and having a curved shape; and
a connection plate connected above the curvature movement portion.

7. The bonding apparatus of claim 1, wherein, in a plan view, the sub-support portion is provided in plural and is arranged at each of both sides of the main support portion.

8. The bonding apparatus of claim 1, wherein, in a plan view, the sub-support portion is provided in plural and is arranged at each of an upper side, a lower side, a right side, and a left side of the main support portion.

9. The bonding apparatus of claim 1, wherein the second support unit further comprises a driver driving the main support portion to be rotated, wherein the driver does not drive the sub-support portion.

10. A bonding apparatus for a display apparatus, the bonding apparatus comprising:
a first support unit on which a first panel is mounted; and
a second support unit on which a second panel which is bonded to the first panel is mounted,
wherein the second support unit comprises:
a stage on which the second panel is mounted;
a main support portion arranged below the stage and supporting the stage;
a sub-support portion connected below the stage and arranged to be spaced apart from the main support portion; and
a base plate supporting the main support portion and the sub-support portion,
wherein as the sub-support portion slidingly moves on a plane perpendicular to a rotation axis of the main support portion, the stage is rotated with respect to the main support portion.

11. The bonding apparatus of claim 10, wherein the main support portion and the sub-support portion are arranged to be spaced apart from each other by a first distance, and while the stage is being rotated, the first distance between the main support portion and the sub-support portion is constant.

12. The bonding apparatus of claim 10, wherein, in a plan view, the stage is rotated as the sub-support portion linearly moves in a first direction and a second direction crossing the first direction on the plane.

13. The bonding apparatus of claim 12, wherein the sub-support portion comprises:
a first linear movement portion arranged on the base plate and linearly moving in the first direction;
a connection plate connected above the first linear movement portion; and
a second linear movement portion arranged on the connection plate and linearly moving in the second direction.

14. The bonding apparatus of claim 10, wherein, in a plan view, as the sub-support portion performs a curve motion with respect to the main support portion, the stage is rotated.

15. The bonding apparatus of claim 14, wherein the sub-support portion comprises:
a curvature movement portion arranged on the base plate and having a curved shape; and
a connection plate connected above the curvature movement portion.

16. The bonding apparatus of claim 10, wherein, in a plan view, the sub-support portion is provided in plural and is arranged at each of both sides of the main support portion.

17. The bonding apparatus of claim 10, wherein, in a plan view, the sub-support portion is provided in plural and is arranged at each of an upper side, a lower side, a right side, and a left side of the main support portion.

18. The bonding apparatus of claim 10, wherein the second support unit further comprises a driver driving the sub-support portion to linearly move the sub-support portion, wherein the driver does not drive the main support portion.

19. A method of manufacturing a display apparatus, the method comprising:
arranging a first panel on a first support unit;
arranging a second panel on a second support unit;
correcting a shaft rotation of the second support unit for the alignment of the second panel; and
pressing the first panel above the second support unit to bond the first panel to the second panel while a portion of the first panel is disposed on the second support unit to overlap the second panel;
wherein the second support unit comprises a stage on which the second panel is mounted, a main support portion arranged below the stage, and a sub-support portion connected below the stage,
wherein the correcting of the shaft rotation comprises a step in which the stage is rotated with the main support portion as a rotation axis as the main support portion is rotated, and the sub-support portion slidingly moves on a plane directed perpendicular to the rotation axis as the stage rotated.

20. A method of manufacturing a electronic device, the method comprising:
manufacturing a display apparatus; and
accommodating the display apparatus in the housing,
wherein manufacturing the display apparatus comprises
arranging a first panel on a first support unit;
arranging a second panel on a second support unit;
correcting a shaft rotation of the second support unit for the alignment of the second panel; and
pressing the first panel above the second support unit to bond the first panel to the second panel while a portion of the first panel is disposed on the second support unit to overlap the second panel;
wherein the second support unit comprises a stage on which the second panel is mounted, a main support portion arranged below the stage, and a sub-support portion connected below the stage,
wherein the correcting of the shaft rotation comprises a step in which the stage is rotated with the main support portion as a rotation axis as the main support portion is rotated, and the sub-support portion slidingly moves on a plane directed perpendicular to the rotation axis as the stage rotated.
